(19) United States
(12) Patent Application Publication
(10) Pub. No.: US 2012/0080085 A1
(43) Pub. Date: Apr. 5, 2012

(54) Patterned protected film

(75) Inventors: Christian C. HONEKER, Acton, MA (US); Robert L. Febonio, Hudson, NH (US); Jean-Philippe Mulet, Montreuil (FR); Mathieu Berard, Paris (FR)

(73) Assignee: SAINT-GOBAIN PERFORMANCE PLASTICS CORPORATION, Aurora, OH (US)

(21) Appl. No.: 13/220,659

(22) Filed: Aug. 29, 2011

Related U.S. Application Data
(60) Provisional application No. 61/378,742, filed on Aug. 31, 2010.

(51) Int. Cl. H01L 31/0236; H01L 31/18; B32B 3/30

(52) U.S. Cl. 136/256; 428/172; 156/220

(57) ABSTRACT

A film has an inner and an outer surface. The film includes a first layer forming the outer surface and including fluoropolymer. The film further includes a second layer disposed away from the outer surface comprising a polymer. The polymer can have a storage modulus at 65° C. of at least 5 MPa. The film has a plurality of surface features forming the outer surface and extending into the first and second layers. The surface features have a mean slope of at least 15°. The film can be applied as a protective film overlying an active component of a photovoltaic device.

### CROSS-REFERENCE TO RELATED APPLICATION(S)

The present application claims priority from U.S. Provisional Patent Application No. 61/378,742, filed Aug. 31, 2010, entitled “PATTERNED PROTECTIVE FILM”, naming inventors Christian C. Honeker, Robert L. Febonio, Jean-Philippe Mulet, and Mathieu Berard, which application is incorporated by reference herein in its entirety.

### FIELD OF THE DISCLOSURE

This disclosure, in general, relates to polymer films having a surface pattern, photovoltaic devices including such patterned films, and methods for forming such photovoltaic devices.

### BACKGROUND

With increasing concern over the environment and an increasing interest in alternative energy sources, industry is turning to photovoltaic devices for generating power. Photovoltaic devices conventionally include an active component that receives sunlight and converts the sunlight into electricity. However, conventional materials useful in making active components are susceptible to damage by exposure to the environment.

Conventional configurations of photovoltaic devices include protective barriers that overlie the active components of the photovoltaic devices. Attempts have been made to use glass and other transparent inorganic materials to form protective barriers. However, such materials are rigid and are susceptible to fracturing in response to impact. As such, rigid inorganic materials are not useful in newer flexible photovoltaic devices and have limitations when used in other photovoltaic devices that may be exposed to hail or other storm damage. In addition, attempts have been made to use polymeric materials that have more flexibility, but tend to have limited transparency resulting in, at best, at least a partial degradation in solar collection efficiency.

As such, an improved protective film and photovoltaic device would be desirable.

### BRIEF DESCRIPTION OF THE DRAWINGS

The present disclosure may be better understood, and its numerous features and advantages made apparent to those skilled in the art by referencing the accompanying drawings.

FIG. 1 includes an illustration of an exemplary photovoltaic device.

FIG. 2 includes an illustration of a portion of an exemplary photovoltaic device.

FIG. 3 includes an illustration of a cross section of an exemplary protective film.

FIG. 4 includes an illustration of a plan view of a photovoltaic film.

FIG. 5 includes a graph of texture ratio versus mean slope.

FIG. 6 includes a graph illustrating the effect of encapsulant on texture ratio.

FIG. 7 and FIG. 8 include graph illustrations of the softening properties of polymer samples.

The use of the same reference symbols in different drawings indicates similar or identical items.

### DETAILED DESCRIPTION

In an exemplary embodiment, a film includes a protective layer forming an outer surface of the film and includes an encapsulant sheet to be disposed closer to an active component of a photovoltaic device than the protective layer. In an example, the protective layer is formed of a fluoropolymer. The encapsulant sheet includes a layer having desirable thermomechanical properties, such as a storage modulus at 65° C. of at least 5 MPa. The protective film can be attached to an active component of a photovoltaic device. For example, the protective film forms an outer surface of the photovoltaic device and the encapsulant sheet is in contact with a surface of the active component. The protective film includes a plurality of surface features that provide the outer surface with a mean slope averaged over the outer surface of at least 15° with respect to a surface of the active component to which the film is to be attached. In an example, the plurality of surface features extends inward into the protective film. In particular, the plurality of surface features can displace a portion of the encapsulant sheet so that the outer surface is formed of the protective layer and the thickness of the encapsulant sheet varies to compensate for the indentation of the surface features.

In a further exemplary embodiment, a method of forming a photovoltaic device includes dispensing a protective film including a protective layer and an encapsulant sheet and attaching the protective film to the active component of the photovoltaic device. The encapsulant sheet is in contact with a surface of the active component and the protective layer forms an outer surface of the photovoltaic device. The protective film includes a plurality of surface features, for example, extending inward toward the active component, providing an outer surface having a mean slope of at least 15°. The method can also include patterning the film to form the plurality of surface features. For example, attaching the protective film can include laminating the protective film to the active component, and patterning can be performed concurrently with laminating. Alternatively, patterning can be performed prior to attaching the protective film, while attaching the protective film, or after attaching the protective film.

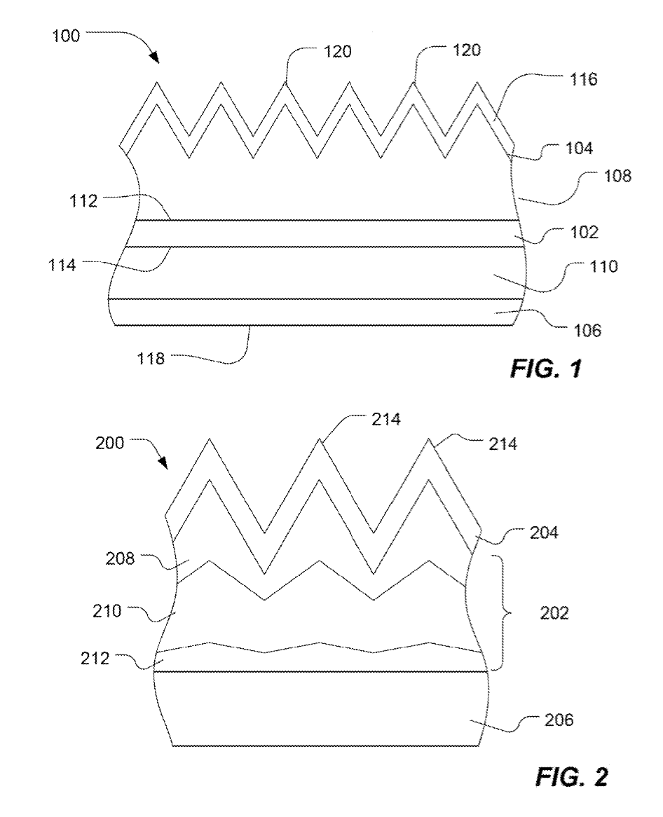

Turning to the figures, FIG. 1 includes an illustration of an exemplary photovoltaic device 100 that includes an active component 102 having a front surface 112 and a back surface 114. In an example, the active component 102 is a single-sided photovoltaic component that receives sunlight on its front surface 112 and converts the sunlight into electricity. In such an embodiment, the back surface 114 can be formed of a support material, supporting the light converting devices. Alternatively, the back surface 114 can also include light converting devices and as such, can convert reflected light or light received at different parts of the day into electricity. The photovoltaic device 100 can be a rigid photovoltaic device or a flexible photovoltaic device. In a particular example, the photovoltaic device 100 is a flexible photovoltaic device.

An encapsulant sheet 108 is disposed on the front surface 112 of the active component 102 and a protective layer 104 is disposed on the encapsulant sheet 108. The protective layer 104 forms a front surface 116 of the photovoltaic device 100. Optionally, an encapsulant sheet 110 can be disposed on a back surface 114 of the active component 102 and a further protective layer 106 can be formed on the encapsulant sheet 110. The protective layer 106 forms a back surface 118 of the photovoltaic device 100. The protective layers 104 or 106 can include surface features 120, which may or may not influence the thickness of the encapsulant sheets 108 or 110.

The encapsulant sheets 108 and 110 can be formed of the same materials or can be formed of different materials. In particular, the encapsulant sheets 108 and 110 are formed of polymeric materials, such as olefinic copolymers, vinyl acetate copolymers, acrylate copolymers, functionalized polyolefin, polyurethane, polyvinyl butyral polymers, silicone, fluoropolymers, or any combination thereof. In particular, the encapsulant sheets 108 and 110 can be formed of ethylene copolymers with alkyl acrylic acids. In an example, the alkyl acrylic acid is a methacrylic acid, an ethyl acrylic acid, a propyl acrylic acid, or any combination thereof. In a further example, the polymer can be an ionomer of the alkyl acrylic acid copolymer. For example, the ionomer can include a counterion, such as a lithium, sodium, zinc, magnesium, calcium, or potassium ion, or any combination thereof. In a particular example, the ionomer is a zinc ionomer of a copolymer of ethylene and methacrylic acid.

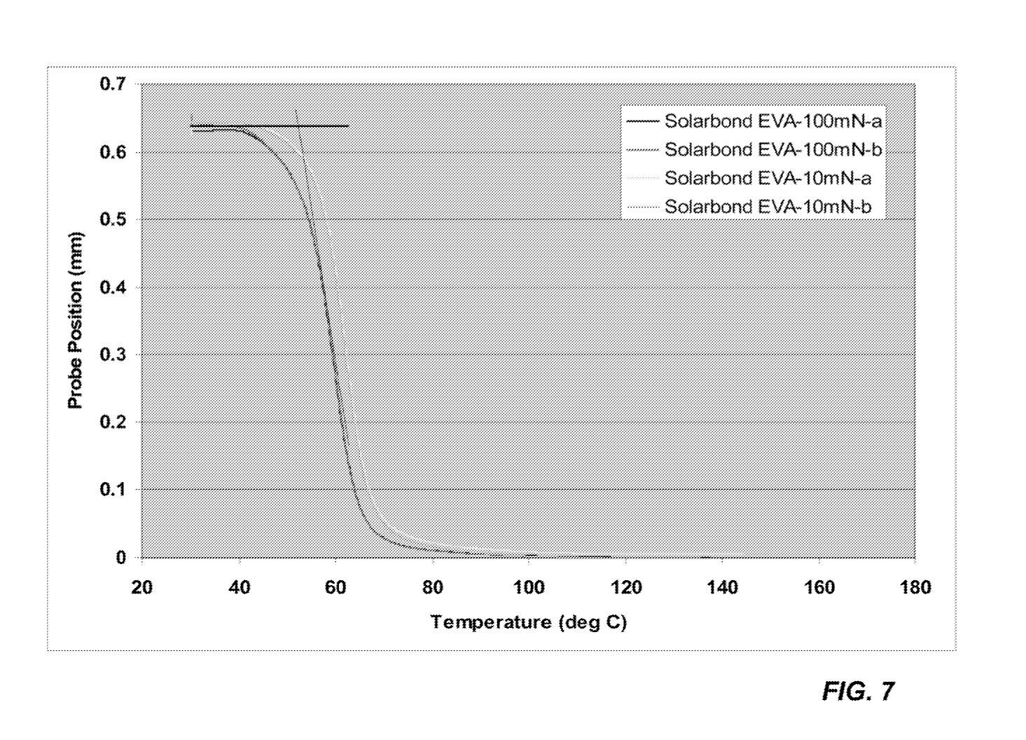

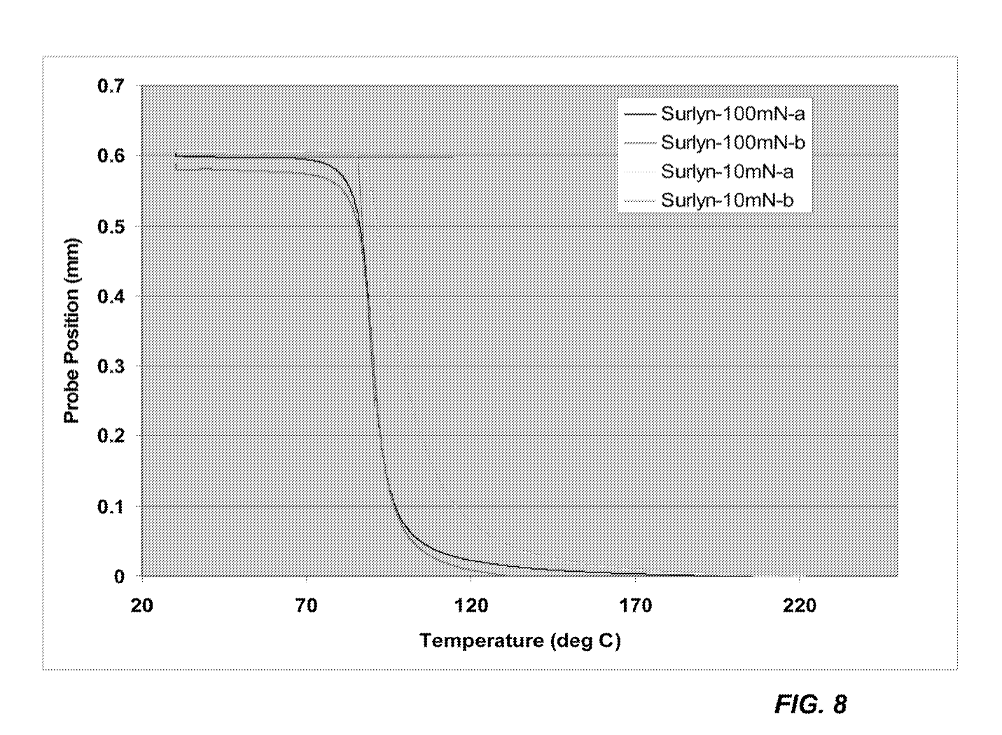

In an example, the encapsulant sheets 108 or 110 include a layer of polymer having desirable thermomechanical properties. For example, the polymer having the desirable thermomechanical properties can have a desirable onset temperature and inflection point temperature as measured using a Perkin Elmer TMA 7 with the penetration probe with a 1 mm diameter specified by Perkin Elmer. When measured using a force of 10 mN and a heating rate of 5° C./min, the onset temperature (defined as the temperature at which the probe begins to penetrate the sample) is at least 55° C., such as at least 60° C., at least 65° C., or even at least 70° C. When measured using a 100 mN force and the same heating rate, the onset temperature is at least 75° C., such as at least 80° C., at least 82.5° C., or even at least 85° C. Further, when measured using 10 mN force and the same heating rate, the inflection point temperature (defined as the temperature when the change in slope relative to temperature changes from negative to positive with increasing temperature) is at least 70° C., such as at least 80° C., at least 85° C., or even at least 90° C. When measured using 100 mN, the inflection point temperature is at least 85° C., such as at least 90° C., at least 95° C., or even at least 99° C. FIG. 8 includes a graph illustration of the analysis of a Surlyn® ionomer sample. In contrast, FIG. 7 includes an illustration of a Solarbond® EVA sample.

In another example, the polymer can have a desirable storage modulus measured in accordance with ASTM D4065, D4440, or D5279. For example, the storage modulus of the polymeric layer within the encapsulant layers 108 or 110 is at least 5 MPa at 65° C. In an example, the storage modulus at 65° C. is at least 8 MPa, such as at least 10 MPa, or even at least 12 MPa. In a further example, the storage modulus at 50° C. can be at least 10 MPa, such as at least 15 MPa, at least 18 MPa, or even at least 20 MPa. The storage modulus at 65° C. can be not greater than 200 MPa.

Further, the polymer layer within the encapsulant sheets 108 or 110 can have a desirable melt flow rate, such as a melt flow rate of not greater than 6.0 g/10 min as determined by ASTM D1238 at 190° C. and using 2.16 kg. For example, the melt flow rate can be not greater than 5.5 g/10 min, such as not greater than 3.5 g/10 min, not greater than 2.5 g/10 min, or even not greater than 1.0 g/10 min.

In an additional example, the polymer layer within the encapsulant sheets 108 or 110 can have a desirable Vicat softening point of at least 55° C. as determined in accordance with ASTM D1525. For example, the polymer layer can have a Vicat softening point of at least 60° C., such as at least 64° C. In addition, the polymer can have a desirable hardness, such as a hardness (Shore A) of at least 60. In an example, the Shore A hardness can be at least 70, such as at least 72. Further, a polymer layer within the encapsulant sheets 108 or 110 can have a desirable tensile modulus (ASTM D5026) of at least 15 MPa at 23° C. For example, the tensile modulus can be in a range of 18 MPa to 500 MPa, such as a range of 18 MPa to 400 MPa.

The protective layers 104 and 106 can be formed of a fluoropolymer. The fluoropolymer can be a homopolymer of fluorine-substituted monomers or a copolymer including at least one fluorine-substituted monomer. Exemplary fluorine substituted monomers include tetrafluoroethylene (TFE), vinylidene fluoride (VF2), hexafluoropropylene (HFP), chlorotrifluoroethylene (CTFE), perfluoroethylvinyl ether (PEVE), perfluoromethylvinyl ether (PMVE), and perfluoropropylvinyl ether (PPVE). Examples of fluorinated polymers include polytetrafluoroethylene (PTFE), perfluoroalkylvinyl ether (PFA), fluorinated ethylene-propylene copolymer (FEP), ethylene tetrafluoroethylene copolymer (ETFE), polyvinylidene fluoride (PVDF), polychlorotrifluoroethylene (PCTFE), TFE copolymers with VF2 or HFP, ethylene chlorotrifluoroethylene copolymer (ECTFE), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), or any combination thereof. In particular, the fluoropolymer is melt processable. For example, the fluoropolymer can be polyvinylidene fluoride (PVDF), ethylene tetrafluoroethylene copolymer (ETFE), polychlorotrifluoroethylene (PCTFE), ethylene chlorotrifluoroethylene copolymer (ECTFE), fluorinated ethylene propylene copolymer (FEP), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), or any combination thereof. For example, the fluoropolymer can be a fluorinated ethylene propylene copolymer (FEP). In another example, the fluoropolymer can be a copolymer of ethylene and tetrafluoroethylene (ETFE).

In a particular example, the polymer layer of the encapsulant sheets 108 or 110 having the desirable thermal mechanical properties can be in direct contact with the protective layer 104 or 106, such as without intervening layers or adhesives. In an alternative example, the encapsulant sheets 108 or 110 can include more than one layer, at least one of which has the desirable thermomechanical properties. For example, as illustrated in FIG. 2, a partial cross section of a photovoltaic device can include an active component 206, an encapsulant sheet 202 disposed on the active component 206, and a protective layer 204 disposed on the encapsulant sheet 202. The encapsulant sheet 202 can be formed of more than one layer. As illustrated, the encapsulant sheet 202 includes layers 208, 210, and 212. One or more of the layers 208, 210 and 212 can include polymers having desirable thermomechanical properties. Surface features 214 formed in the protective layer 204 may or may not influence the thickness of the encapsulant sheet 202 or its respective layers, e.g., 208, 210, or 212.

In a particular example, the layers 208 and 212 include a polymer having desirable thermomechanical properties. The layers 208 and 212 can include polymers having enhanced adhesive properties, improved lamination properties, or other desirable properties. Alternatively, the layer 210 can include polymers having desirable thermomechanical properties

In a particular example, the layer 210 can include a polymer selected from polyolefin, a copolymer of ethylene and vinyl acetate, vinyl acetate copolymer, acrylate copolymer, functionalized polyolefin, polyurethane, polyvinyl butyral, silicone, fluoropolymer, or any combination thereof. An exemplary polymer includes natural or synthetic polymers, including polyethylene (including linear low density polyethylene, low density polyethylene, high density polyethylene, etc.); polypropylene; nylons (polyamides); EPDM; polyesters; polycarbonates; ethylene-propylene copolymers; copolymers of ethylene or propylene with acrylic or methacrylic acids; acrylates; methacrylates; poly alpha olefin melt adhesives such including, for example, ethylene vinyl acetate (EVA), ethylene butyl acrylate (EBA), ethylene methyl acrylate (EMA), ionomers (e.g., acid functionalized polyolefins generally neutralized as a metal salt), or acid functionalized polyolefins; polyurethanes including, for example, thermoplastic polyurethane (TPU); olefin elastomers; olefinic block copolymers; thermoplastic silicones; polyvinyl butyral; a fluoropolymer, such as a terpolymer of tetrafluoroethylene, hexafluoropropylene, and vinylidene fluoride (THV); or any combination thereof.

The layer 210 can form between 50 vol % and 90 vol % of the encapsulant sheet, such as between 60 vol % and 85 vol %, or between 75 vol % and 85 vol %. The layers 208 or 212 can each form between 5 vol % and 25 vol %, such as between 7.5 vol % and 20 vol %, or between 7.5 vol % and 12.5 vol %.

The polymer layers illustrated in FIG. 1 or FIG. 2 can include other additives such as fillers, ultraviolet absorbers, antioxidants and free radical scavengers, desiccants or getters, processing aids, or any combination thereof.

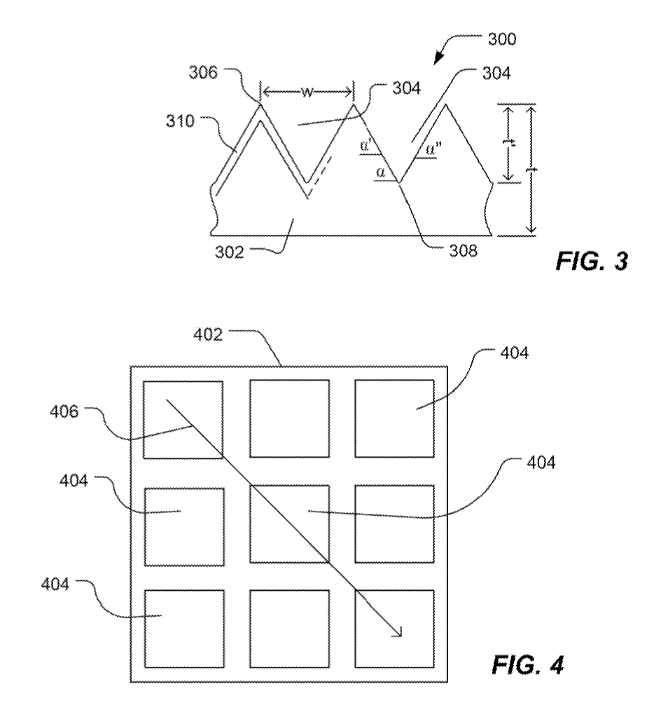

While not illustrated in FIG. 1 or FIG. 2, the protective film, including the protective layer and the encapsulant sheet, includes a plurality of surface features. For example, the plurality of surface features can be negative surface features defined by the outer protective layer and formed through displacement of portions of the encapsulant sheet so that the encapsulant sheet has varying thickness. For example, FIG. 3 includes an illustration of an exemplary protective film 300. The protective film 300 includes encapsulant sheet 302 and protective layer 310. A plurality of surface features 304, illustrated as negative surface features, is formed into the protective film, forming peaks 306 and valleys 308. Alternatively, the surface features can be positive surface features extending from the surface as protruding features.

In a particular example, the plurality of surface features provides an outer surface having a mean slope, defined as the slope of the surface relative to planes parallel to an active component or underside of the protective film averaged (mean) across the surface, of at least 15°. For example, at a given point, the surface can have a slope (α, α′, α″) relative to an active component on which the protective film is disposed. The slopes (α, α′, α″) are averaged to determine a mean slope. In particular, the mean slope can be at least 20°, such as at least 25°, at least 28°, at least 30°, at least 36°, or even at least 40°. The mean slope is calculated as described below in the examples.

In another embodiment, the mean slope can be not greater than 80°, such as not greater than 70°, not greater than 65°, not greater than 60°, not greater than 55°, not greater than 50°, or even not greater than 45°.

The surface features can be prismatic rows or pyramidal structures. In another example, the surface features can be sinusoidal or semispherical. In particular, the surface features 304 are negative pyramidal structures, extending inwardly. Each surface feature of the plurality of surface features can have a cross-sectional dimension (w), defined as the maximum dimension parallel to an underside of the protective film. The cross-sectional dimension (w) can be in a range of 0.01 mm to 5 mm, such as a range of 0.02 mm to 5 mm, or even a range of 0.035 mm to 3 mm. Further, a surface feature can have a depth (t′) orthogonal to the cross-sectional dimension (w) in a range of 0.1 mm to 10 mm, such as a range of 0.2 mm to 5 mm, or even a range of 0.5 mm to 2 mm.

The protective film 300 can have a maximum thickness (t) in a range of a range of 20 μm to 1000 μm, such as a range of 50 μm to 1000 μm, a range of 150 μm to 1000 μm, a range of 200 μm to 800 μm, or even a range of 400 μm to 700 μm. The protective layer 310 can have a desirable thickness. For example, the protective layer can have an average thickness in a range of 12 μm to 75 μm, such as a range of 12 μm to 55 μm, or a range of 20 μm to 51 μm. A polymer layer 302 having desirable thermomechanical properties within the encapsulant sheets can have a desirable maximum thickness. For example, the maximum thickness of the polymer layer 302 can be in a range of 20 μm to 1000 μm, such as a range of 50 μm to 1000 μm, a range of 150 μm to 1000 μ, a range of 200 μm to 800 μm, or even a range of 400 μm to 700 μm.

In an example, a photovoltaic device can be formed by applying a protective film having a plurality of surface features having a mean slope of at least 15° to an active component of a photovoltaic device. The protective film can be patterned in advance of applying, patterned during applying, or patterned after applying. In a particular example, a protective film is dispensed. The protective film includes a first layer forming an outer surface of the film and comprising fluoropolymer. In addition, the protective film includes a second layer to be disposed between the first layer and an active component of the photovoltaic device. The second layer includes a polymer having desirable thermomechanical properties. In a particular example, the second layer can be in direct contact with the first layer. Alternatively, additional layers can be disposed between the second layer and the first layer or can be disposed between the second layer and the surface of the active component to which the film is to be attached.

The protective film is applied to the surface of an active component. In an example, the protective film can be laminated to the surface of the active component, such as through heat lamination. Alternatively, an adhesive can be applied and the film adhered to the surface of the active component.

In addition, the protective film is patterned to provide a plurality of surface features. The surface features can be positive surface features, protruding from the film, or a negative surface feature, extending into the film. For example, patterning can include applying a plate that has a plurality of protrusions to form the plurality of surface features. In another example, patterning includes applying a roller including a plurality of protrusions to form the plurality of surface features. In particular, the plate or roller can include a plurality of pyramidal structures that press into the film displacing the encapsulant sheet to leave an outer surface formed of a fluoropolymer, the encapsulant sheet having varying thickness. Patterning can be performed following lamination. Alternatively, patterning can be performed simultaneously or concurrently with lamination. For example, when heat laminating the film to the active component, a patterned tool can be simultaneously used to press the film to the active component of the photovoltaic device.

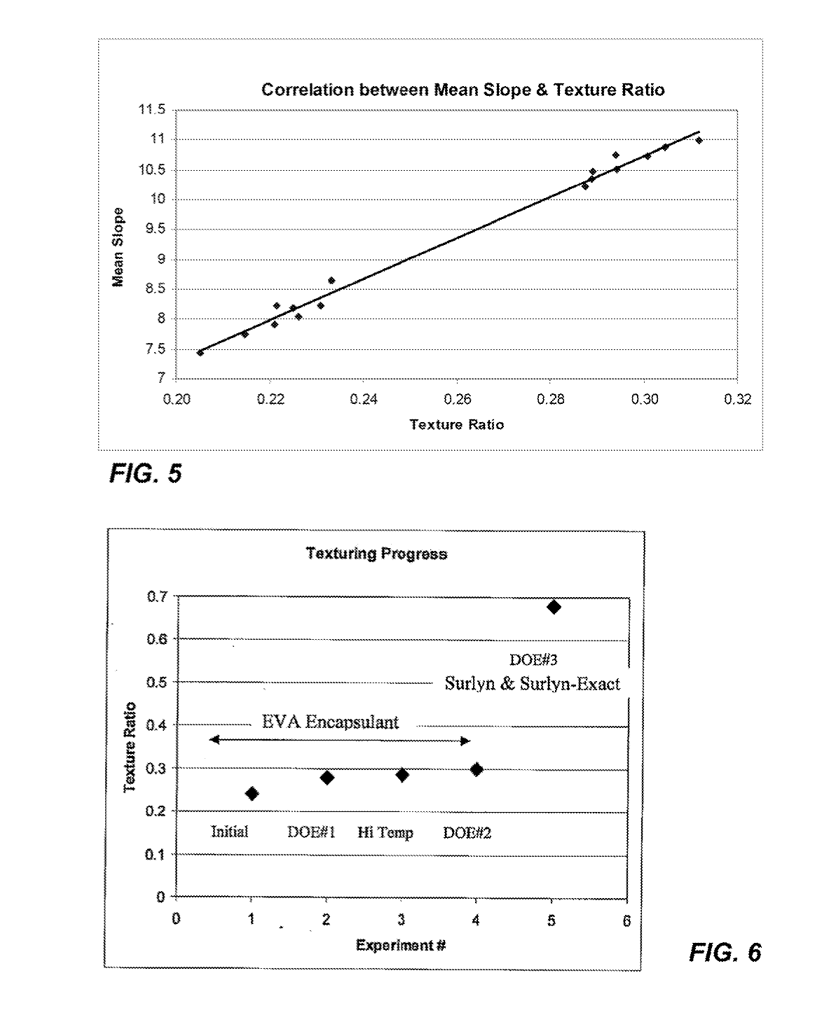

The tool used to form the plurality of surface features can include protrusions that have a characteristic thickness. When applied to the film to produce the plurality of surface features, patterning is typically performed under temperature and pressure. When the tooling is removed, the surface features tend to lose some definition. Applicants have discovered that when using particular layers within the encapsulant sheet that have desirable thermomechanical properties, more definition is retained as characterized by a texture ratio. The texture ratio is a ratio of the maximum depth (t′) of the valleys 308 of the surface feature 304 measured from the peak of the surface feature 306, compared to the maximum depth of the features of the tooling. The texture ratio can be calculated for example for pyramidal structures as illustrated in FIG. 4. When viewed from the top view, the protective film 402 can have a variety of pyramidal surface features 404 extending into the protective film. The depth can be calculated as the average relative height of the peaks along a path 406 that extends through the highest points and the lowest points. In an example, the method of applying the protective film provides a texture ratio of at least 0.4, such as at least 0.45, at least 0.5, at least 0.55, at least 0.60, or even at least 0.65. As demonstrated in the examples, a correlation exists between mean slope and texture ratio (FIG. 5). For a given template, as the texture ratio increases, the mean slope increases. Accordingly, methods that provide desired texture ratios tend to result in the desirable mean slope values in the resulting photovoltaic device.

The photovoltaic device including the protective film has desirably improved conversion efficiency. For example, the overall efficiency for converting light to electricity when averaged over incident angles 0° to 90° increases by at least 0.3% relative to a film of similar construction and average thickness absent the surface features. The incident angle is the angle of light impinging the surface measured relative to the normal to the surface of the active component, i.e., 0° is normal to the surface of the active component. In particular, the improvement in overall efficiency is at least 0.6%, such as at least 0.9%, at least 1.1%, at least 1.4%, at least 1.7%, at least 2.0%, at least 2.8%, at least 3.2%, at least 3.6% or even at least 4.0%. The improvement is even greater at incident angles greater than 50°. For example, the improvement in efficiency relative to a film free of surface structures when measured at an incident angle of 60° is at least 2.5%, such as at least 2.9%, at least 3.3%, at least 4.0%, at least 5.0%, at least 6.0%, at least 7.0%, or even at least 8.0%.

### EXAMPLES

Samples are prepared by heat laminating a protective film to a flexible photovoltaic component available from UniSolar. A surface feature template is placed on a PTFE release fabric within a laminator (Model L036A available from P Energy). A protective layer and encapsulant sheet are placed on the template so that the protective layer is in contact with the template. The flexible photovoltaic component is placed active side down in contact with the encapsulant sheet. A second PTFE release fabric is placed over the flexible photovoltaic component. Unless otherwise stated, the sample is pressed for at least 5 minutes at 145° C.

The surface topology of the patterned samples is measured using optical profilometry using an optical profiler available from ZeMetrics. The surface is labeled with a gold coating sputtered onto the surface. Mean slope is determined by converting height map data into slope data. The slope map can be converted to a slope histogram and the mean slope determined from the slope histogram.

The texture ratio is the ratio of the maximum texture depth within the sample divided by the maximum texture depth within the template. The texture depth of the sample is determined by extracting a line profile from the height map and averaging the peak to valley heights of the features along the line. The line extends through the maxima and minima of the surface features. As illustrated in FIG. 5, the mean slope and texture ratio are correlated for samples prepared in accordance with the examples below.

### Example 1

Samples are prepared using a variety of templates. The template is selected from paper (U/S Univ Fibra available from Sappi company of Michigan), screen (Brite aluminum insect screening, Phifer Wire Products, Inc. of Tuscaloosa, Ala.), glass (Albarino P available from Saint-Gobain), or plate 1 (22.5 Mold #3 having 22.5 pyramids/in available from Valco Precision Machine of Brockton, Mass.)\. The samples include a 1 mil ETFE layer and a 26 mil EVA encapsulant sheet. Table 1 illustrates the efficiency gain and mean slope associated with the photovoltaic devices associated with the templates.

TABLE 1
Effect of Templates

| Template | Efficiency Gain (%) | Mean Slope (°) |
|---|---|---|
| Reference (Flat) | 0.00 | 0 |
| Paper | −0.03 | 1.35 |
| Screen | 0.24 | 5.02 |
| Plate 1 (22.5 Mold #3) | −0.01 | 2.20 |
| Albarino P (Sample #1) | 0.49 | 6.82 |
| Albarino P (Sample #2) | 0.76 | 8.55 |

The samples with the highest mean slope and efficiency gain are those textured with the Albarino P glass template. The highest efficiency gain from this set of experiments is 0.76% at a mean slope of 8.55°.

Extrapolating these data indicate that materials having a mean slope of at least 15 degrees have an efficiency gain with particular advantages for photovoltaic productivity, light transmission and/or commercial applicability.

### Example 2

Samples are prepared with different protective layers of different thickness and patterned with one of two templates. The thicknesses are selected from 1 mil and 2 mils. The template is selected from 1 mm grooves (1 mm spacing peak-to-peak) and Albarino P. The polymer of the protective layers is selected from FEP and ETFE. The samples include a 26 mil EVA encapsulant layer. Table 2 illustrates the maximum depth and texture ratio (avg. for two samples) for the samples patterned with 1 mm grooves. Table 3 illustrates the maximum depth and texture ratio (avg. for two samples) for samples patterned with Albarino P. The samples are pressed for at least 5 minutes at 145° C.

TABLE 2
Texture Ratio for Groove Patterned Samples

| | Thickness | | Texture |
|---|---|---|---|
| SAMPLE | (mil) | Material | Ratio |
| 1 | 1 | ETFE | 0.094 |
| 2 | 2 | ETFE | 0.105 |
| 3 | 1 | FEP | 0.12 |
| 4 | 2 | FEP | 0.098 |

TABLE 3
Texture Ratio for Albarino P Patterned Samples

| | Thickness | | Texture |
|---|---|---|---|
| SAMPLE | (mil) | Material | Ratio |
| 5 | 1 | ETFE | 0.251 |
| 6 | 2 | ETFE | 0.202 |
| 7 | 1 | FEP | 0.282 |
| 8 | 2 | FEP | 0.222 |

Analysis of the samples patterned with the 1 mm groove template indicates that there is little correlation between texture ratio and layer thickness or polymer type. In contrast, analysis of the samples patterned with Albarino P template show a strong influence of thickness and polymer type on texture ratio. The highest texture ratio is found when the protective layer is FEP of 1 mil thickness and a pattern of Albarino P.

### Example 3

Samples are prepared using different lamination temperatures: 145° C. and 200° C. The samples include a 1 mil ETFE layer and a 26 mil EVA encapsulant sheet The samples are patterned with either 1 mm grooves or Albarino P templates. Table 4 illustrates the texture ratio of the samples.

TABLE 4
Effect of Temperature on Texture Ratio

| | | Lamination Temperature (° C.) | |
|---|---|---|---|
| Sample | | 145 | 200 |
| 9 | 1 mil ETFE Grooves | TR = 0.094 | TR = 0.12 |
| | | | MS = 4.4 |
| 10 | 1 mil ETFE Albarino P | TR = 0.255 | TR = 0.285 |
| | | | MS = 10.2 |

TR—Texture Ratio
MS—Mean Slope (°)

As illustrated in Table 4, texture ratio increases for samples patterned with greater temperature.

### Example 4

Samples are prepared varying the thickness of the encapsulant sheet, the lamination temperature and the press time. The thickness of the EVA encapsulant sheet is 26 mils or 52 mils. The lamination temperature is 200° C. or 220° C., and the press time is 3 minutes or 12 minutes. Table 5 illustrates the mean slope and texture ratio of the samples.

TABLE 5
Effect of Parameters on Mean Slope and Texture Ratio

| | Temp | Encap. Thick | Press Time | Mean | Texture |
|---|---|---|---|---|---|
| Sample | (° C.) | (mils) | (Sec) | Slope (°) | Ratio |
| 11 | 200 | 26 | 240 | 10.6 | 0.295 |
| 12 | 200 | 26 | 720 | 10.3 | 0.29 |
| 13 | 200 | 52 | 240 | 8.4 | 0.23 |
| 14 | 200 | 52 | 720 | 8.1 | 0.22 |
| 15 | 220 | 26 | 240 | 10.8 | 0.295 |
| 16 | 220 | 26 | 720 | 10.7 | 0.20 |
| 17 | 220 | 52 | 240 | 7.8 | 0.215 |
| 18 | 220 | 52 | 720 | 7.9 | 0.22 |

As illustrated in Table 5, encapsulant thickness influences the mean slope and texture ratio. The lower thickness encapsulant sheets provide a higher mean slope and texture ratio.

### Example 5

Samples are prepared with different encapsulant sheets of 26 mil thickness and different lamination temperatures. Each sample includes a 2 mil ETFE protective layer. The lamination temperature is selected from 200° C. and 230° C. The encapsulant layer is selected from a single layer of an ionomer of a copolymer of ethylene and methacrylic acid (Surlyn 1705 available from Dupont) and a multilayer encapsulant sheet including layers of the ionomer. The multilayer encapsulant sheet includes an olefin layer between two ionomer layers. The olefin layer (Exact 3131 LDPE available from ExxonMobil) forms 80 vol % of the encapsulant sheet and each of the ionomer layers (Surlyn 1705) forms 10% of the encapsulant sheet.

The ionomer has a storage modulus at 50° C. of approximately 20.5 MPa and a storage modulus at 65° C. of approximately 12.5 MPa. In contrast, EVA exhibits a storage modulus at 50° C. of approximately 5 MPa and at 65° C. of approximately 2.5 MPa. Table 6 illustrates the influence of lamination temperature and encapsulant material on texture ratio.

TABLE 6
Influence of Encapsulant on Texture Ratio

| | | Temp. | Avg. Texture | |
|---|---|---|---|---|
| Sample | Encapsulant | (° C.) | Ratio | Mean Slope |
| 19 | Ionomer | 200 | 0.49 | Not measured |
| 20 | Ionomer | 230 | 0.49 | Not measured |
| 21 | Multilayer | 200 | 0.54 | Not measured |
| 22 | Multilayer | 230 | 0.68 | 21.1 |

The texture ratio of samples including either the single layer ionomer encapsulant sheet or the multilayer ionomer encapsulant sheet exceeds previous samples. In particular, the multilayer encapsulant sheet provides a texture ratio of 0.68. In particular, the total thickness of the protective film is 711 micrometers, whereas the thickness of the Albarino P template is 982 micrometers. As such, the texture ratio of 0.68 is approaching the maximum texture ratio achievable for a protective film of thickness 711 micrometers.

Further, FIG. 6 includes a graph of the average texture ratios for samples tested in each of the Examples above. As evidenced by FIG. 6, the ionomer-containing encapsulant sheets provided significantly improved texture ratio over other samples.

In a first embodiment, a film has an inner and an outer surface. The film includes a first layer forming the outer surface, and a second layer disposed away from the outer surface comprising a polymer. The film has a plurality of surface features forming the outer surface and extending into the first and second layers, the surface features having a mean slope of at least 15°.

In an example of the first embodiment, the plurality of surface features are pyramidal surface features. In another example, each surface feature of the plurality of surface features has a cross-section in a range of 0.01 mm to 5 mm, such as a range of 0.02 mm to 5 mm, or a range of 0.02 mm to 3 mm.

In a further example of the first embodiment, the polymer includes a copolymer of ethylene and an acrylic acid. For example, the acrylic acid is a methacrylic acid. The polymer can be an ionomer. The ionomer can include zinc.

In another example of the first embodiment, the first layer includes fluoropolymer. The fluoropolymer can be selected from the group consisting of polytetrafluoroethylene (PTFE), perfluoroalkylvinyl ether (PFA), fluorinated ethylene-propylene copolymer (FEP), ethylene tetrafluoroethylene copolymer (ETFE), polyvinylidene fluoride (PVDF), polychlorotrifluoroethylene (PCTFE), THE copolymers with VF2 or HFP, ethylene chlorotrifluoroethylene copolymer (ECTFE), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), and a combination thereof. For example, fluoropolymer is melt processable. In another example, the fluoropolymer is fluorinated ethylene propylene. In a further example, the fluoropolymer is a copolymer of ethylene and tetrafluoroethylene.

In an additional example of the first embodiment, the second layer is in direct contact with the first layer.

In an example of the first embodiment, the film further includes a third layer disposed between the first layer and the second layer. The third layer can include polyolefin.

In another example, the mean slope is at least 20°, such as at least 25°, at least 28°, at least 30°, or at least 32°. In a further example of the first embodiment, the polymer of the second layer has a storage modulus at 65° C. of at least 5 MPa, such as at least 8 MPa, at least 10 MPa, or at least 12 MPa. The polymer can have a storage modulus at 50° C. of at least 10 MPa, such as at least 15 MPa, at least 18 MPa, or at least 20 MPa.

In an additional example of the first embodiment, the polymer of the second layer has an onset temperature of at least 55° C. when measured using 10 mN force when measured using a 1 mm diameter penetration probe specified by Perkin Elmer. In another example of the first embodiment, the polymer of the second layer has a inflection point temperature of at least 70° C. when measured using a 10 mN force. In a further example, the polymer of the second layer has an onset temperature of at least 75° C. when measured using 100 mN force. In another example, the polymer of the second layer has a inflection point temperature of at least 85° C. when measured using a 100 mN force.

In a further example of the first embodiment, the polymer has a melt flow rate of not greater than 6.0 g/10 min, such as not greater than 5.5 g/10 min, not greater than 3.5 g/10 min, not greater than 2.5 g/10 min, or not greater than 1.0 g/10 min. In an additional example, the polymer has a Vicat softening point of at least 55° C., such as at least 60° C., or at least 64° C.

In another example of the first embodiment, the polymer has a Shore A hardness of at least 60, such as at least 70, or at least 72. In an additional example, the polymer has a tensile modulus of at least 15 MPa, such as in a range of 18 MPa to 500 MPa, or a range of 18 MPa to 400 MPa.

In a further example of the first embodiment, the first layer has a thickness in a range of 12 μm to 100 μm, such as a range of 12 μm to 75 μm, a range of 12 μm to 55 μ, or a range of 20 μm to 51 μm. In another example, the second layer has a thickness in a range of 20 μm to 1000 μm, such as a range of 50 μm to 1000 μm, a range of 150 μm to 1000 μm, a range of 200 μm to 800 μm, or a range of 400 μm to 700 μm.

In a second embodiment, a photovoltaic device includes an active component and a protective film overlying a surface of the active component. The film includes a first layer forming the outer surface and a second layer disposed between the first layer and the active component. The second layer includes a polymer. The protective film has surface features with a mean slope of at least 15°.

In an example of the second embodiment, the active component is a flexible photovoltaic device. In another example of the second embodiment, the active component is a rigid photovoltaic device.

In an additional example of the second embodiment, the polymer includes a copolymer of ethylene and an acrylic acid. For example, the acrylic acid is a methacrylic acid. The polymer can be an ionomer. The ionomer can include zinc.

In a further example, the first layer includes a fluoropolymer. The fluoropolymer can be selected from the group consisting of polytetrafluoroethylene (PTFE), perfluoroalkylvinyl ether (PFA), fluorinated ethylene-propylene copolymer (FEP), ethylene tetrafluoroethylene copolymer (ETFE), polyvinylidene fluoride (PVDF), polychlorotrifluoroethylene (PCTFE), TFE copolymers with VF2 or HFP, ethylene chlorotrifluoroethylene copolymer (ECTFE), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), and a combination thereof. The fluoropolymer can be melt processable. The fluoropolymer can be fluorinated ethylene propylene. In another example, the fluoropolymer can be a copolymer of ethylene and tetrafluoroethylene.

In an additional example of the second embodiment, the second layer is in direct contact with the first layer. In another example of the second embodiment, the film further includes a third layer disposed between the first layer and the second layer. The third layer can include polyolefin.

In another example of the second embodiment, the mean slope of the surface features is at least 20°, such as at least 25°. In a further example, the polymer has a storage modulus at 65° C. of at least 8 MPa. In an additional example, the polymer has a storage modulus at 50° C. of at least 10 MPa.

In an example of the second embodiment, the polymer of the second layer has an onset temperature of at least 55° C. when measured using 10 mN force when measured using a 1 mm penetration probe as specified by Perkin Elmer. In another example, the polymer of the second layer has a inflection point temperature of at least 70° C. when measured using a 10 mN force. In an additional example, the polymer of the second layer has an onset temperature of at least 75° C. when measured using 100 mN force. In an example, the polymer of the second layer has a inflection point temperature of at least 85° C. when measured using a 100 mN force.

In an example of the second embodiment, the polymer has a melt flow rate of not greater than 6.0 g/10 min. In an additional example, the first layer has a thickness in a range of 12 μm to 75 μm. In another example, the second layer has a thickness in a range of 20 μm to 1000 ∞m.

In a third embodiment, a method of forming a photovoltaic device including dispensing a film. The film includes a first layer forming the outer surface and a second layer disposed between the first layer and the active component. The second layer includes a polymer. The method further includes laminating the film to a surface of an active component and patterning the film to provide a plurality of surface features having a texture ratio of at least 0.4.

In an example of the third embodiment, patterning and laminating are performed concurrently. In another example, patterning includes applying a plate including a plurality of protrusions forming the plurality of surface features. In an additional example, patterning includes applying a roller including a plurality of protrusions forming the plurality of surface features. In a further example, patterning to provide the plurality of surface features includes patterning to form a plurality of pyramidal surface features.

In another example of the third embodiment, each surface feature of the plurality of surface features has a cross-section in a range of 0.1 mm to 10 mm, such as a range of 0.2 mm to 5 mm, or a range of 0.5 mm to 2 mm.

In a further example of the third embodiment, the texture ratio is a least 0.45, such as at least 0.5, at least 0.55, at least 0.60, or at least 0.65.

In a fourth embodiment, a film having an inner and an outer surface. The film includes a first layer forming the outer surface and comprising fluoropolymer and includes a second layer comprising an ionomer formed of a copolymer of ethylene and methacrylic acid. The surface features of the film has a mean slope of at least 15°.

According to embodiments herein, protective film structures are described that have notable advantages over the prior art in terms of photovoltaic productivity and light throughput. While certain embodiments take advantages of various modes of texturing a film, it is noted that other modes have been utilized with photovoltaic devices. For example, embossing a film with channels and contours was employed to manage heat extraction from the photovoltaic device as can be seen in U.S. Pat. No. 7,851,694. Channels and contours resulting from such embossing mediate gas or air flow across the film and not light transmission or photovoltaic productivity; the features are not configured or structured to manage light transmission. Additionally, photovoltaic elements with such a de-airing feature can include a flat top layer such as a glass sheet or fluoropolymer sheet (planar). Accordingly, embodiments in the prior art containing a fluoropolymer sheet do not have a structured surface pattern on the outer layer.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

What is claimed is:

1. A film having an inner and an outer surface, the film comprising:
a first layer forming the outer surface; and
a second layer underlying the first layer comprising a polymer;
wherein the film has a plurality of surface features defining the outer surface, the surface features having a mean slope of at least 15°.

2. The film of claim 1, wherein the plurality of surface features are pyramidal surface features.

3. The film of claim 1, wherein each surface feature of the plurality of surface features has a cross-section in a range of 0.01 mm to 5 mm.

4. The film of claim 3, wherein the cross-section is in a range of 0.02 mm to 5 mm.

5. The film of claim 4, wherein the cross-section is in range of 0.02 mm to 3 mm.

6. The film of claim 1, wherein the polymer includes a copolymer of ethylene and an acrylic acid.

7. The film of claim 6, wherein the acrylic acid is a methacrylic acid.

8. The film of claim 1, wherein the polymer is an ionomer.

9. The film of claim 8, wherein the ionomer includes zinc.

10. The film of claim 1, wherein the first layer comprises fluoropolymer.

11. The film of claim 10, wherein the fluoropolymer is selected from the group consisting of polytetrafluoroethylene (PTFE), perfluoroalkylvinyl ether (PFA), fluorinated ethylene-propylene copolymer (FEP), ethylene tetrafluoroethylene copolymer (ETFE), polyvinylidene fluoride (PVDF), polychlorotrifluoroethylene (PCTFE), TEE copolymers with VF2 or HFP, ethylene chlorotrifluoroethylene copolymer (ECTFE), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), and a combination thereof.

12. The film of claim 10, wherein the fluoropolymer is melt processable.

13. The film of claim 10, wherein the fluoropolymer is fluorinated ethylene propylene.

14. The film of claim 10, wherein the fluoropolymer is a copolymer of ethylene and tetrafluoroethylene.

15. The film of claim 1, wherein the second layer is in direct contact with the first layer.

16. The film of claim 1, further comprising a third layer disposed between the first layer and the second layer.

17. The film of claim 16, wherein the third layer comprises polyolefin or ionomer.

18. The film of claim 1, wherein the mean slope is at least 20°.

19. The film of claim 18, wherein the mean slope is at least 25°.

20. The film of claim 19, wherein the mean slope is at least 28°.

21. The film of claim 20, wherein the mean slope is at least 30°.

22. The film of claim 21, wherein the mean slope is at least 32°.

23. The film of claim 1, wherein the polymer of the second layer has a storage modulus at 65° C. of at least 5 MPa

24. The film of claim 23, wherein the storage modulus at 65° C. is at least 8 MPa.

25. The film of claim 24, wherein the storage modulus at 65° C. is at least 10 MPa.

26. The film of claim 25, wherein the storage modulus at 65° C. is at least 12 MPa.

27. The film of claim 1, wherein the polymer of the second layer has a storage modulus at 50° C. of at least 10 MPa.

28. The film of claim 27, wherein the storage modulus at 50° C. is at least 15 MPa.

29. The film of claim 28, wherein the storage modulus at 50° C. is at least 18 MPa.

30. The film of claim 29, wherein the storage modulus at 50° C. is at least 20 MPa.

31. The film of claim 1, wherein the polymer of the second layer has an onset temperature of at least 55° C. when measured using 10 mN force when using a 1 mm penetration probe.

32. The film of claim 1, wherein the polymer of the second layer has a inflection point temperature of at least 70° C. when measured using a 10 mN force when using a 1 mm penetration probe.

33. The film of claim 1, wherein the polymer of the second layer has an onset temperature of at least 75° C. when measured using 100 mN force when using a 1 mm penetration probe.

34. The film of claim 1, wherein the polymer of the second layer has a inflection point temperature of at least 85° C. when measured using a 100 mN force when using a 1 mm penetration probe.

35. The film of claim 1, wherein the polymer has a melt flow rate of not greater than 6.0 g/10 min.

36. The film of claim 35, wherein the melt flow rate is not greater than 5.5 g/10 min.

37. The film of claim 36, wherein the melt flow rate is not greater than 3.5 g/10 min.

38. The film of claim 37, wherein the melt flow rate is not greater than 2.5 g/10 min.

39. The film of claim 38, wherein the melt flow rate is not greater than 1.0 g/10 min.

40. The film of claim 1, wherein the polymer has a Vicat softening point of at least 55° C.

41. The film of claim 40, wherein the Vicat softening point is at least 60° C.

42. The film of claim 41, wherein the Vicat softening point is at least 64° C.

43. The film of claim 1, wherein the polymer has a Shore A hardness of at least 60.

44. The film of claim 43, wherein the Shore A hardness is at least 70.

45. The film of claim 44, wherein the Shore A hardness is at least 72.

46. The film of claim 1, wherein the polymer has a tensile modulus of at least 15 MPa.

47. The film of claim 46, wherein the tensile modulus is in a range of 18 MPa to 500 MPa.

48. The film of claim 47, wherein the tensile modulus is in a range of 18 MPa to 400 MPa.

49. The film of claim 1, wherein the first layer has a thickness in a range of 12 μm to 100 μm.

50. The film of claim 49, wherein the thickness is in a range of 12 μm to 55 μm.

51. The film of claim 50, wherein the thickness is in a range of 20 μm to 51 μm.

52. The film of claim 1, wherein the second layer has a thickness in a range of 20 μm to 1000 μm.

53. The film of claim 52, wherein the thickness is in a range of 50 μm to 1000 μm.

54. The film of claim 53, wherein the thickness is in a range of 150 μm to 1000 μm.

55. The film of claim 54, wherein the thickness is in a range of 200 μm to 800 μm.

56. The film of claim 55, wherein the thickness is in a range of 400 μm to 700 μm.

57. A photovoltaic device comprising:
an active component; and
a film overlying a surface of the active component, the film comprising:
a first layer forming the outer surface; and
a second layer disposed between the first layer and the active component, the second layer comprising a polymer;
wherein the film has a mean slope of at least 15°.

58. The photovoltaic device of claim 57, wherein the active component is a flexible photovoltaic device.

59. The photovoltaic device of claim 57, wherein the active component is a rigid photovoltaic device.

60. The photovoltaic device of claim 57, wherein the polymer includes a copolymer of ethylene and an acrylic acid.

61. The photovoltaic device of claim 60, wherein the acrylic acid is a methacrylic acid.

62. The photovoltaic device of claim 57, wherein the polymer is an ionomer.

63. The photovoltaic device of claim 62, wherein the ionomer includes zinc.

64. The photovoltaic device of claim 57, wherein the first layer comprises a fluoropolymer.

65. The photovoltaic device of claim 64, wherein the fluoropolymer is selected from the group consisting of polytetrafluoroethylene (PTFE), perfluoroalkylvinyl ether (PFA), fluorinated ethylene-propylene copolymer (FEP), ethylene tetrafluoroethylene copolymer (ETFE), polyvinylidene fluoride (PVDF), polychlorotrifluoroethylene (PCTFE), TFE copolymers with VF2 or HFP, ethylene chlorotrifluoroethylene copolymer (ECTFE), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), and a combination thereof.

66. The photovoltaic device of claim 57, wherein the fluoropolymer is melt processable.

67. The photovoltaic device of claim 57, wherein the fluoropolymer is fluorinated ethylene propylene.

68. The photovoltaic device of claim 57, wherein the fluoropolymer is a copolymer of ethylene and tetrafluoroethylene.

69. The photovoltaic device of claim 57, wherein the second layer is in direct contact with the first layer.

70. The photovoltaic device of claim 57, further comprising a third layer disposed between the first layer and the second layer.

71. The photovoltaic device of claim 70, wherein the third layer comprises polyolefin or ionomer.

72. The photovoltaic device of claim 57, wherein the mean slope is at least 20°.

73. The photovoltaic device of claim 72, wherein the mean slope is at least 25°.

74. The photovoltaic device of claim 57, wherein the polymer has a storage modulus at 65° C. of at least 8 MPa.

75. The photovoltaic device of claim 57, wherein the polymer has a storage modulus at 50° C. of at least 10 MPa.

76. The film of claim 57, wherein the polymer of the second layer has an onset temperature of at least 55° C. when measured using 10 mN force when using a 1 mm penetration probe.

77. The film of claim 57, wherein the polymer of the second layer has a inflection point temperature of at least 70° C. when measured using a 10 mN force when using a 1 mm penetration probe.

78. The film of claim 57, wherein the polymer of the second layer has an onset temperature of at least 75° C. when measured using 100 mN force when using a 1 mm penetration probe.

79. The film of claim 57, wherein the polymer of the second layer has a inflection point temperature of at least 85° C. when measured using a 100 mN force when using a 1 mm penetration probe.

80. The photovoltaic device of claim 57, wherein the polymer has a melt flow rate of not greater than 6.0 g/10 min.

81. The photovoltaic device of claim 57, wherein the first layer has a thickness in a range of 12 μm to 75 μm.

82. The photovoltaic device of claim 57, wherein the second layer has a thickness in a range of 20 μm to 1000 μm.

83. A method of forming a photovoltaic device, the method comprising:
dispensing a film comprising:
a first layer forming the outer surface; and
a second layer disposed between the first layer and the active component, the second layer comprising a polymer;
laminating the film to a surface of an active component; and
patterning the film to provide a plurality of surface features having a texture ratio of at least 0.4.

84. The method of claim 83, wherein patterning and laminating are performed concurrently.

85. The method of claim 83, wherein patterning includes applying a plate including a plurality of protrusions forming the plurality of surface features.

86. The method of claim 83, wherein patterning includes applying a roller including a plurality of protrusions forming the plurality of surface features.

87. The method of claim 83, wherein patterning to provide the plurality of surface features includes patterning to form a plurality of pyramidal surface features.

88. The method of claim 83, wherein each surface feature of the plurality of surface features has a cross-section in a range of 0.2 mm to 10 mm.

89. The method of claim 88, wherein the cross-section is in a range of 0.2 mm to 5 mm.

90. The film of claim 89, wherein the cross-section is in range of 0.5 mm to 2 mm.

91. The method of claim 83, wherein the texture ratio is a least 0.45.

92. The method of claim 91, wherein the texture ratio is at least 0.5.

93. The method of claim 92, wherein the texture ratio is at least 0.55.

94. The method of claim 93, wherein the texture ratio is at least 0.60.

95. The method of claim 94, wherein the texture ratio is at least 0.65.

96. A film having an inner and an outer surface, the film comprising:
a first layer forming the outer surface and comprising fluoropolymer; and
a second layer comprising an ionomer formed of a copolymer of ethylene and methacrylic acid;
wherein the film has a mean slope of at least 15°.

97. A film having an inner and an outer surface, the film comprising:
a first layer forming the outer surface and comprising fluoropolymer; and
a second layer underlying the first layer comprising a polymer;
wherein the film has a plurality of surface features defining the outer surface, the surface features having a mean slope of at least 15°.

98. A photovoltaic device comprising:
an active component; and
a film overlying a surface of the active component, the film comprising:
a first layer forming an outer surface; and
a second layer disposed between the first layer and the surface of the active component, the second layer comprising a polymer;
wherein the film has a plurality of surface features defining the outer surface, the surface features having a mean slope of at least 15°.
